(19) United States
(12) Patent Application Publication
(10) Pub. No.: US 2026/0332090 A1
(43) Pub. Date: Oct. 22, 2026

(54) PHOTOVOLTAIC MODULE

(71) Applicant: LG INNOTEK CO., LTD., Seoul (KR)

(72) Inventors: Kwang Soon JUNG, Seoul (KR); Soo Hong KIM, Seoul (KR); Mi Sun LEE, Seoul (KR); Seung Min LEE, Seoul (KR)

(73) Assignee: LG INNOTEK CO., LTD., Seoul (KR)

(21) Appl. No.: 19/116,910

(22) PCT Filed: Sep. 27, 2023
(86) PCT No.: PCT/KR2023/015153

§ 371 Date: Mar. 28, 2025

(30) Foreign Application Priority Data
Sep. 30, 2022 (KR) 10-2022-0125806
Sep. 30, 2022 (KR) 10-2022-0125807

(51) Int. Cl. H02S 40/36; H02M 1/00; H02M 3/00; H02M 3/158; H02S 40/34; H10F 19/90; H10F 77/00

(52) U.S. Cl. CPC H02S 40/36; H02M 1/0077; H02M 3/003; H02M 3/158; H02S 40/345; H10F 19/902; H10F 77/955

(57) ABSTRACT

An optimizer module according to an embodiment of the present invention comprises: two input terminals connected to a cell string; a power conversion unit for converting power inputted via the input terminals; two output terminals connected to another optimizer module or the outside; and a control unit for controlling the power conversion unit in response to the power inputted via the input terminals.

### TECHNICAL FIELD

The present invention relates to photovoltaic modules, and more particularly to photovoltaic modules in which optimizers are connected individually to each photovoltaic cell string.

### BACKGROUND ARTS

Solar power generation is an eco-friendly energy generation method that is replacing conventional chemical and nuclear power generation and is becoming widely used. Solar power generation can be either stand-alone, where the battery is connected to a converter, or grid-connected, which is connected to the power grid. Generally, stand-alone power generation is composed of photovoltaic cells, storage batteries, and power converters, while grid-connected systems are connected to commercial power sources and are configured to exchange power with the load line.

The maximum power point of a photovoltaic module varies depending on the amount of sunlight and temperature. To operate the solar cell at the maximum power point, an optimizer or module-level power electronics (MLPE) can be used to control the maximum power point tracking (MPPT) at the module level.

A junction box is installed on the photovoltaic module to connect it to an external line. To connect the optimizer to the photovoltaic module, a large number of cables and manual work are required. There is also the disadvantage that a separate device must be installed to prevent electric shock on the photovoltaic module depending on the installation environment.

### SUMMARY OF THE INVENTION

### Technical Subject

The technical challenge that this invention seeks to solve is to provide a photovoltaic module in which the optimizer is connected individually to each photovoltaic cell string.

### Technical Solution

To solve the above-mentioned technical problems, an optimizer module according to one exemplary embodiment of the present invention may comprise: a case body; a case cover covering the case body; and an optimizer disposed inside the case body, wherein the optimizer includes two input terminals and two output terminals.

Preferably, but not necessarily, the two input terminals may be connected to the output terminals at both ends of the cell string, and the optimizer may include: a power conversion unit that converts the output power of the cell string; and a control unit that controls the power conversion unit according to the output power of the cell string.

Preferably, but not necessarily, the output terminals may be connected to another optimizer module or an external device.

Preferably, but not necessarily, the output terminal may be connected in series when connected to another optimizer module.

Preferably, but not necessarily, the inside of the case body may be filled with a heat dissipating material.

Preferably, but not necessarily, the case body and case cover may be formed of waterproof structure.

Preferably, but not necessarily, the optimizer may be attached to and detached from the case body.

Preferably, but not necessarily, the optimizer may include a bypass unit connected in parallel between the two output terminals.

Preferably, but not necessarily, the optimizer may include an auxiliary power unit that generates an auxiliary power source using the output power of the cell string.

To solve the above-mentioned technical problems, a photovoltaic module according to an exemplary embodiment of the present invention may comprise: a photovoltaic panel including a plurality of cell strings; and a plurality of optimizer modules each controlling the output power of each of the cell strings, wherein the optimizer module includes one of the optimizer modules.

Preferably, but not necessarily, each of the optimizer modules may be spaced apart from each other and disposed in the area corresponding to each cell string.

Preferably, but not necessarily, each of the optimizer modules may be connected in series with each other through the connection unit embedded in the photovoltaic panel.

Preferably, but not necessarily, each of the optimizer modules may be connected to each other via a connection unit outside the photovoltaic panel, or to an optimizer module of an external or other photovoltaic module.

To solve the above-mentioned technical problems, the optimizer module according to the second exemplary embodiment of the present invention may comprise: two input terminals connected to the cell string; a power conversion unit converting the power inputted to the input terminals; two output terminals connected to another optimizer module or an external source; and a control unit controlling the power conversion unit according to the power input to the input terminals.

Preferably, but not necessarily, the control unit may control the power conversion unit so that the output power of the cell string is maximized.

Preferably, but not necessarily, the power conversion unit may include at least one of a buck converter, a boost converter, and a buck-boost converter.

Preferably, but not necessarily, the power conversion unit may include a bypass unit connected in parallel between the two output terminals.

Preferably, but not necessarily, the bypass unit may be conductive when the first current outputted from the power conversion unit is lower than the second current flowing through the output terminal.

Preferably, but not necessarily, the bypass unit may include a diode. Preferably, but not necessarily, the bypass unit may include an auxiliary power unit that generates an auxiliary power using the power inputted to the input terminal.

Preferably, but not necessarily, the auxiliary power unit may operate in step-down mode or step-up mode.

To solve the above-mentioned technical problems, a photovoltaic module according to the second embodiment of the present invention may comprise: a photovoltaic panel including a plurality of cell strings; and a plurality of optimizer modules each controlling the output power of each of the cell strings, wherein the optimizer module includes one of the optimizer modules.

Preferably, but not necessarily, each of the above optimizer modules may be spaced apart and disposed in the area corresponding to each cell string.

### Advantageous Effects

According to embodiments of the present invention, it is possible to reduce the number of cables for connecting photovoltaic panels and optimizers and to facilitate work.

### BRIEF DESCRIPTION OF DRAWINGS

FIG. 1 is a block diagram of a photovoltaic module according to one embodiment of the present invention.

FIG. 2 is a drawing for explaining the maximum power point tracking control.

FIG. 3 is a block diagram that specifies the relationship between the cell string and the optimizer according to an embodiment of the present invention.

FIG. 4 shows the connection between optimizers according to an embodiment of the present invention.

FIG. 5 shows the position of each optimizer according to an embodiment of the present invention.

FIG. 6 shows an embodiment of a photovoltaic module according to an exemplary embodiment of the present invention.

FIG. 7 is a block diagram of an optimizer module according to an embodiment of the present invention.

FIG. 8 shows an embodiment of an optimizer module according to an exemplary embodiment of the present invention.

FIG. 9 is a block diagram of a photovoltaic module according to another embodiment of the present invention.

FIG. 10 is a perspective view of an optimizer module according to an embodiment of the present invention.

FIG. 11 shows the inside of the case of an optimizer module according to an embodiment of the present invention.

FIG. 12 shows the connected relationship of multiple optimizer modules according to an embodiment of the present invention.

FIG. 13 is a block diagram of a photovoltaic module according to another embodiment of the present invention.

FIG. 14 shows the connected relationship of multiple photovoltaic modules according to an embodiment of the present invention.

### BEST MODE

Hereinafter, exemplary embodiments of the present invention will be described in detail with reference to the accompanying drawings.

However, the present invention is not limited to the given exemplary embodiments described, but may be implemented in a variety of different forms, and one or more of components among the exemplary embodiments may be optionally combined or substituted between embodiments within the scope of the present invention.

Furthermore, terms (including technical and scientific terms) used in the embodiments of the present invention, unless expressly specifically defined and described, are to be interpreted in the sense in which they would be understood by a person of ordinary skill in the art to which the present invention belongs, and commonly used terms, such as dictionary-defined terms, are to be interpreted in light of their contextual meaning in the relevant art.

Furthermore, the terms used in the embodiments of the invention are intended to describe the embodiments and are not intended to limit the invention.

In this specification, the singular may include the plural unless the context otherwise requires, and references to “at least one (or more) of A and (or) B and C” may include one or more of any combination of A, B, and C that may be assembled.

In addition, the terms first, second, A, B, (a), (b), and the like may be used to describe components of embodiments of the invention. Such terms are intended only to distinguish one component from another, and are not intended to limit the nature or sequence or order of such components by such terms.

Furthermore, when a component is described as “connected,” “coupled,” or “attached” to another component, it can include cases where the component is “connected,” “coupled,” or “attached” to the other component directly, as well as cases where the component is “connected,” “coupled,” or “attached” to another component that is between the component and the other component.

Furthermore, when described as being formed or disposed “above” or “below” each component, “above” or “below” includes not only when two components are in direct contact with each other, but also when one or more other components are formed or disposed between the two components. Furthermore, when expressed as “above” or “below”, it may include the meaning of upward as well as downward with respect to a single component. The variant examples according to this embodiment may include some configuration of each embodiment and some configurations of another embodiment. In other words, the variant example may include one embodiment of various embodiments, but some configurations are omitted and some configurations of another embodiment corresponding to the omitted configurations are included. Or, it may be the other way around. The features, structures, and effects described in the embodiments are included in at least one embodiment and are not necessarily limited to only one embodiment. Furthermore, the features, structures, and effects illustrated in each embodiment can be combined or modified with respect to other embodiments by a person having ordinary knowledge in the field to which the embodiments belong. Therefore, the contents related to such combinations and modifications should be interpreted as being included in the scope of embodiments.

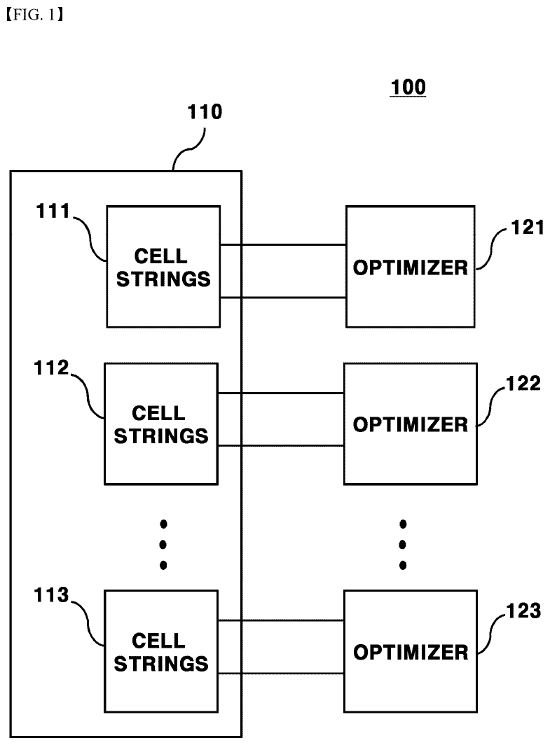

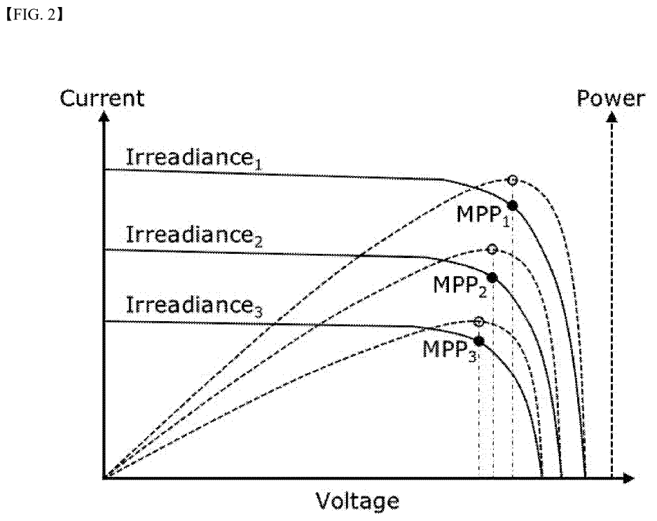

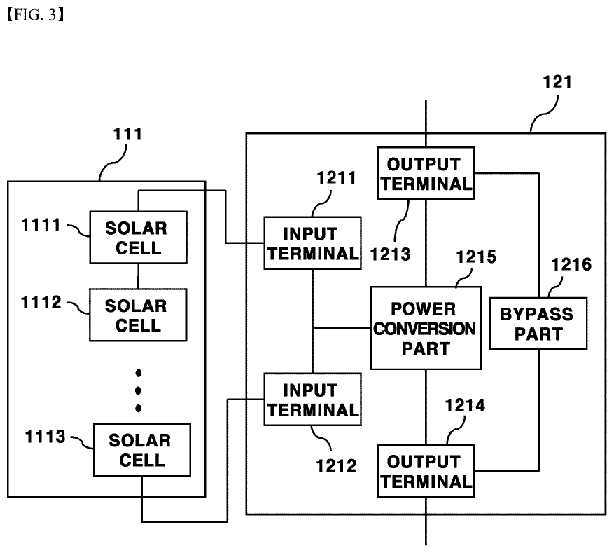

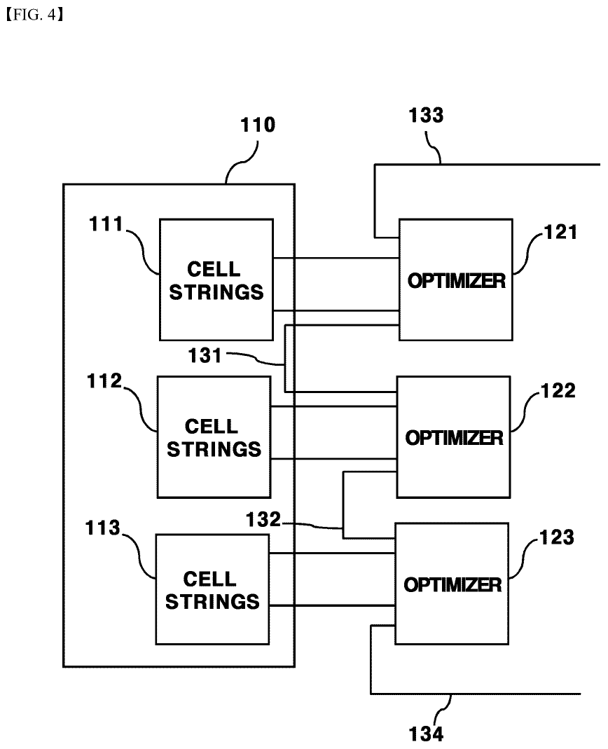

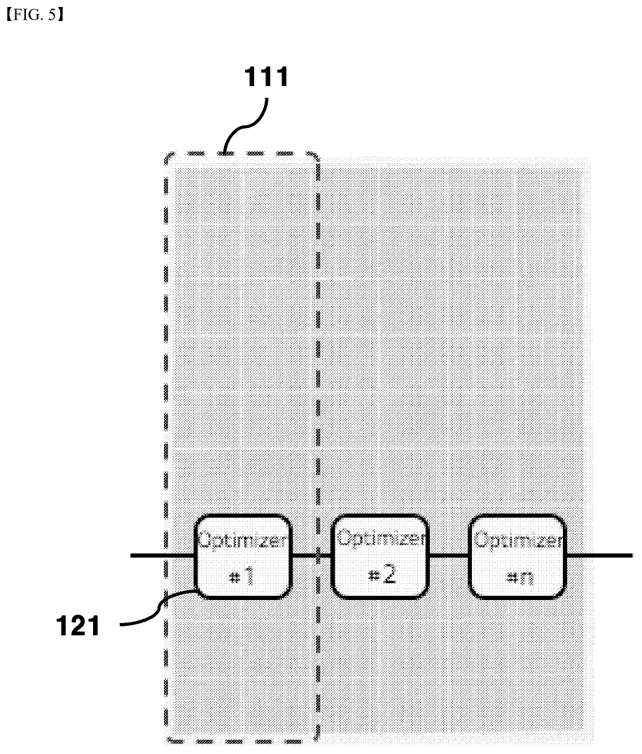

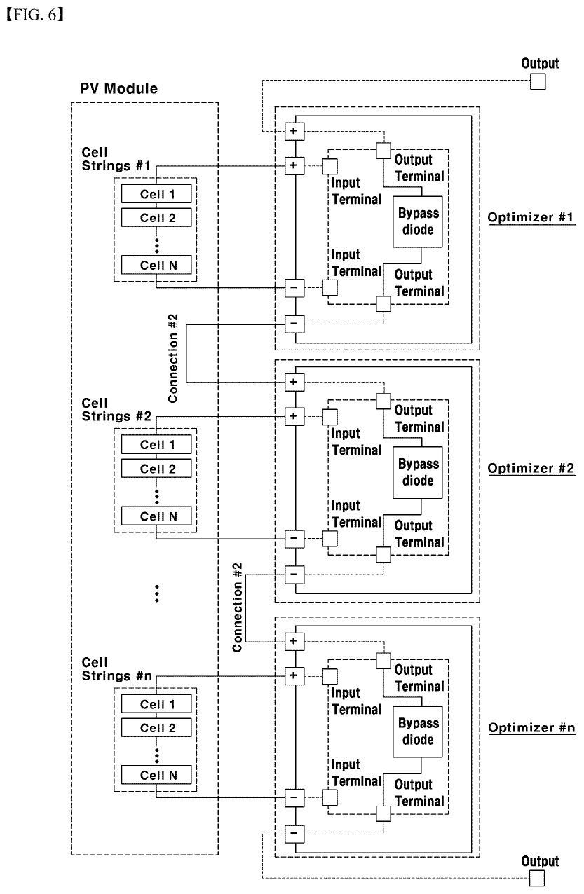

FIG. 1 is a block diagram of a photovoltaic module according to one embodiment of the present invention, FIG. 2 is a drawing for explaining the maximum power point tracking control, FIG. 3 is a block diagram that specifies the relationship between the cell string and the optimizer according to an embodiment of the present invention, FIG. 4 shows the connection between optimizers according to an embodiment of the present invention, FIG. 5 shows the position of each optimizer according to an embodiment of the present invention, and FIG. 6 shows an embodiment of a photovoltaic module according to an exemplary embodiment of the present invention.

The photovoltaic module (100) according to an embodiment of the present invention may include a photovoltaic panel (110) and a plurality of optimizers (121, 122, 123).

A photovoltaic module according to an embodiment of the present invention may be a module that converts the power generated by a photovoltaic panel into power suitable for a load or battery. It may be expressed as a solar module, a solar power module, etc.

A photovoltaic panel (110) may include a plurality of cell strings. Solar cells that perform solar power generation may be expressed as a unit of a cell string in which a plurality of cells is connected in series.

A cell string may include at least one cell, and if it includes multiple cells, the multiple cells may be connected in series. A cell string may be a solar cell string that includes a photovoltaic cell. A solar cell string may form a photovoltaic (PV) panel. A photovoltaic panel (110) may also be referred to as a solar panel or a solar PV panel. Solar cells generate electricity using the photovoltaic effect.

The photovoltaic effect is the emission of electrons when light of a certain frequency or higher hits a certain metal material. Electricity is generated by forming a pn junction using a P-type semiconductor and an N-type semiconductor, and using the electrons generated by the photovoltaic effect to generate current. Solar cells are formed using silicon and can be formed in the form of wafers. Solar cells are located on the exterior walls, rooftops, etc. of fields or buildings that can receive sunlight well, and generate electricity using sunlight. At this time, solar cells can be formed as BIPV (Building Integrated Photovoltaics), which is formed as an integral part of the building.

Since the amount of power generated by a single solar cell is insufficient for use in a load or power system, a string of solar cells may be connected in series, rather than a single solar cell, to form a solar cell string that generates power at a suitable size for use. A solar cell string may be the basic unit for generating electricity. Multiple basic units, cell strings, may be formed into panels to create a solar power panel. Solar cells have different voltage-current characteristics depending on the amount of sunlight and temperature, as shown in FIG. 2, and the maximum power point (MPP) also fluctuates. (Power generated=voltage×current)

Multiple optimizers (121, 122, 123) may control the output power of each of the above cell strings (111).

The optimizer according to an embodiment of the present invention controls the photovoltaic cells to operate at the maximum power point (MPP), which is the operating point at which the photovoltaic cells generate the maximum amount of power under each condition. Here, the optimizer may include module-level power electronics (MLPE).

This is called Maximum Power Point Tracking (MPPT), and the efficiency of solar power generation can be increased by using Maximum Power Point Tracking. In solar power generation, the maximum power may be the power at about 80% of the maximum voltage, not the maximum voltage, depending on the characteristics of the relationship between current and voltage and the relationship between voltage and power. Since the maximum power point keeps changing depending on the magnitude of the voltage and current generated by the photovoltaic panel, the point that can generate the maximum power point must be continuously searched. In other words, the magnitude of the voltage and current can be varied to achieve maximum power, not maximum voltage. In other words, it can reduce the voltage and increase the current in the direction of increasing the power, or increase the voltage and reduce the current.

In order to perform maximum power point tracking for multiple cell strings, individual control of each cell string may be required. For example, if a foreign substance interferes with light reception or a certain cell string is shaded, the power generation level may differ from that of other cell strings, so an operation mode that converts the power output from the cell string as well as an operation other than power conversion may be required. It may be necessary to output the power directly without converting it from the cell string or to bypass the cell string. For each situation, a device with multiple operating modes is required that can operate in the most suitable mode for the power output from each cell string. For example, the optimizer (121) can operate in multiple modes, including power conversion mode (first mode), input/output connection mode (second mode), and bypass mode (third mode), to operate in the most suitable mode for each situation. In addition to the above-mentioned power conversion mode, input/output connection mode, and bypass mode, other operation modes may be included depending on the design.

Each optimizer (121, 122, 123) may be spaced apart from each other and disposed in the area corresponding to each cell string (111, 112, 113). Each of the plurality of optimizers (121, 122, 123) is configured as an independent module, but may be disposed in an area corresponding to each of the cell strings (111, 112, 113) that perform maximum power point tracking in an area of the photovoltaic panel (110). At this time, it can be located in a position corresponding to the output terminal of each cell string (111, 112, 113). In order to individually control each cell string, if one optimizer is used, a large number of cables are required to connect each cell string and the optimizer, and the work of connecting the cables is required. The optimizer according to an embodiment of the present invention includes a plurality of optimizers (121, 122, 123) that are formed separately to individually control each cell string, but the optimizer (121) is disposed in a separate location from the cell string (111), The optimizer (121) may be located on the photovoltaic panel area where each cell string is located, as cables are still required. This allows the optimizer (121), which is individually connected and controlled with the cell string (111), to be directly connected, reducing cable connections and facilitating operation.

The cell strings (111) must receive sunlight, so they are disposed on the first surface of the photovoltaic module (100), and each optimizer (121) may have a separately connected cell string (111) disposed on the second surface, which is the opposite surface of the first surface. On the second surface of the photovoltaic module (100), the output terminals of both ends of the cell string (111) are derived, and the optimizer (121) is disposed at the position where the output terminals of both ends of the cell string (111) are derived, so that it can be directly connected to the input terminals of the optimizer.

The optimizer (121) may include an input terminal (1211, 1212), an output terminal (1213, 1214), a power conversion unit (1215), and a bypass unit (1216).

The input terminals (1211, 1212) may include two input terminals connected to the output terminals at both ends of each cell string (111). As shown in FIG. 3, each cell string (111) may be connected in series with multiple solar cells (1111 to 1113), and the cell strings (111) connected in series have two output terminals at both ends that are externally connected. At this time, the two output terminals may be connected to the second surface of the photovoltaic module (100). The output terminals at both ends of each of the above-mentioned cell strings may be directly connected to the two input terminals (1211, 1212) of the optimizer and the optimizer itself. The two input terminals (1211, 1212) are each connected to the output terminals at both ends of the cell string (111) so that they can receive the power generated by the cell string (111).

The output terminals (1213, 1214) are connected to another optimizer or to the outside. The output terminals (1213, 1214) may also include two output terminals. If the optimizer is connected in series between optimizers, and the optimizer is located between other optimizers, the two output terminals (1213, 1214) are connected to two neighboring optimizers, respectively. The output of multiple optimizers (121, 122) is connected in series to output maximum power to the outside. If the optimizer is located at the position corresponding to the output terminal to the outside, one of the two output terminals (1213, 1214) is connected to another optimizer, and the other is connected to the outside. Here, the outside is a configuration located outside the photovoltaic module, which may be a grid, load, or battery. Or, it may be a power conversion device such as an inverter. The outputs of each optimizer are connected in series and output to the above outside.

The output terminals (1213, 1214) connected to the other optimizers may be connected via the connection unit (131) embedded in the photovoltaic panel (110). As shown in FIG. 4, the optimizer (121) may be connected to the photovoltaic panel (110) via a connection unit (131) built into the photovoltaic panel when connected to another optimizer. The connection unit built into the photovoltaic panel (110) may include a bus bar or a cable. At this time, the output terminal may be directly connected to the bus bar, etc. embedded in the photovoltaic panel (110). At this time, the connection unit (131) embedded in the photovoltaic panel (110) may be drawn to the second surface of the photovoltaic module (100) like the output terminals at both ends of the cell string. The connection unit (131) built into the photovoltaic panel (110) may be directly connected to the two output terminals (1213, 1214) of each optimizer mentioned above inside the optimizer. At this time, the connection unit (131) embedded in the photovoltaic panel (110) may be insulated and formed so that the cell strings and the inside of the photovoltaic panel (110) are not electrically connected to each other. When using the connection unit (131) embedded in the photovoltaic panel (110), the connection location may be limited, but it can be connected directly without a separate cable.

Alternatively, the output terminals (1213, 1214) connected to the other optimizers or the outside may be connected via an external connection (132) rather than the connection embedded in the photovoltaic panel (110). When using the connection unit (132) outside the photovoltaic panel (110), a conductor such as a cable is used, so the connection position or connection form may be freely implemented. However, the cables may be exposed to the outside, increasing the risk of electric shock. Depending on the installation or working environment, the connection unit (131) built into the photovoltaic panel (110) or the connection unit (132) outside the photovoltaic panel (110) may be used.

The power conversion unit (1215) can convert the output power of each cell string (111) inputted through the above input terminals (1211, 1212) and output it to the above output terminals (1213, 1214). The power conversion unit (1215) can convert the voltage of the power of the cell string (111) and output it to the output terminals (1213, 1214). At this time, the power conversion unit (1215) can perform maximum power point tracking for each cell string (111). If some of the cell strings in a plurality of cell strings generate lower voltage than other cell strings due to shading, etc., it is necessary to output the voltage of the other cell strings as is without power conversion to reduce the voltage difference between each cell string to reduce loss and increase efficiency. At this time, the power conversion unit (1215) of each optimizer can adjust the power conversion so that the voltage between the cell strings is equal.

The power conversion unit (1215) may include at least one of a buck converter, a boost converter, and a buck-boost converter. The power conversion unit (120) may include a DC-DC converter, which may include at least one of a buck converter, a boost converter, and a buck-boost converter. The power conversion unit (120) may be implemented as a buck converter that lowers the voltage by comprising an upper switch, a lower switch, and an inductor. It can also be implemented as a boost converter that increases voltage by consisting of an inductor, an upper switch, and a lower switch, and as a buck-boost converter that lowers or increases voltage by consisting of a first upper switch, a first lower switch, an inductor, a second upper switch, and a second lower switch. Capacitors may be connected in parallel to the input and output terminals of each converter.

The bypass unit (1216) is connected in parallel between the two output terminals (1213, 1214).

The bypass unit (1216) can create a bypass path at the output terminals (1213, 1214) that bypasses the connection of the input terminals (1211, 1212) connected to the power conversion unit (120) or the cell string (111). A bypass path may be created to pass the other optimizer externally or to another optimizer without performing power conversion. For example, when a failure occurs in a photovoltaic module containing a cell string, or when there is no power input to the power converter because the input terminals (1211, 1212) are not connected, the bypass unit (1216) can provide a bypass path. In addition, when a hot-spot occurs in the photovoltaic panel, the bypass unit (1216) can also suppress heat generation by providing a bypass path for the output current to lower the current value flowing through the photovoltaic panel. This prevents the increase in the amount of heat generated by the increase in the impedance of the photovoltaic panel when a current greater than the output current of the photovoltaic panel is forced to flow.

The power conversion unit (1215) or the bypass unit (1216) may be operated by the control unit, and the control unit can transmit control signals to each configuration to operate in the most suitable mode according to information such as input/output voltage, current, and temperature. It can also operate in the corresponding mode according to the control signal from the external control unit or the user's input.

As explained earlier, the optimizer that individually controls each cell string (111) is disposed at the position of the corresponding cell string (111), as shown in FIG. 5. A photovoltaic module according to an embodiment of the present invention may be a smart photovoltaic module (PV module) including a cell string optimizer, and may comprise at least one cell string (111) consisting of at least one cell and a cell string optimizer electrically connected to the individual cell strings. The output of the optimizer may be connected in series with another optimizer. As shown in FIG. 6, it can include multiple cell strings and each optimizer, and multiple optimizers may be connected in series (Connection #1) through the conductors embedded in the photovoltaic panel. Alternatively, it may be connected via an external conductor when connected in series (Connection #2). The power generated by the optimizer may be outputted to the output terminal. The optimizer can vary at least one parameter associated with the cell string to optimize the amount of power generated by the corresponding cell string.

The optimizer may include at least one power conversion unit for optimizing the amount of power generated, and the power conversion unit may be configured as a buck, boost, or buck-boost converter. The optimizer may include diodes connected in parallel to the output terminals to optimize the amount of power generated by the photovoltaic module. To prevent electric shock, the optimizer may act to block individual cell string voltages. In addition, the photovoltaic module may include a conductor (cable) for connecting to another photovoltaic module. In addition, the optimizer may be electrically connected to an array consisting of a plurality of cell strings connected in series, in parallel, or in series-parallel. In other words, it may receive input from multiple cell strings rather than from a single cell string.

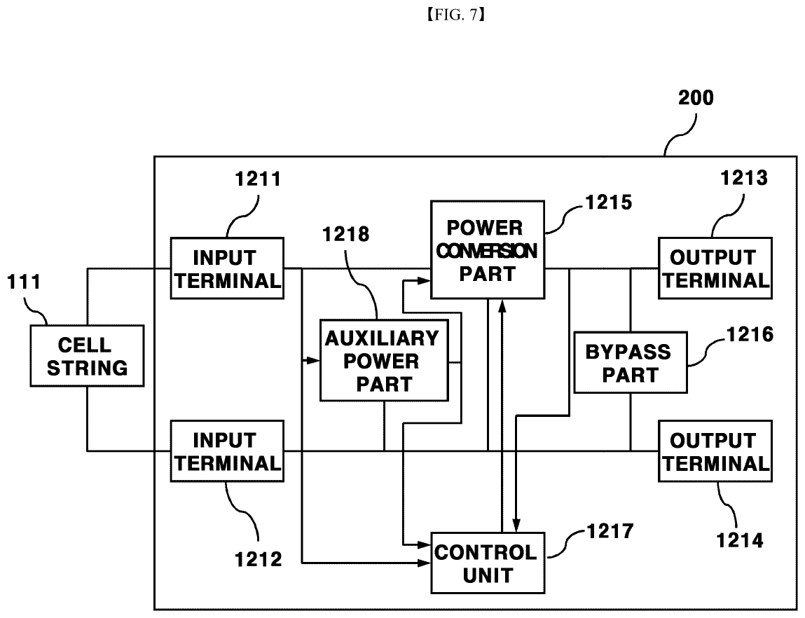

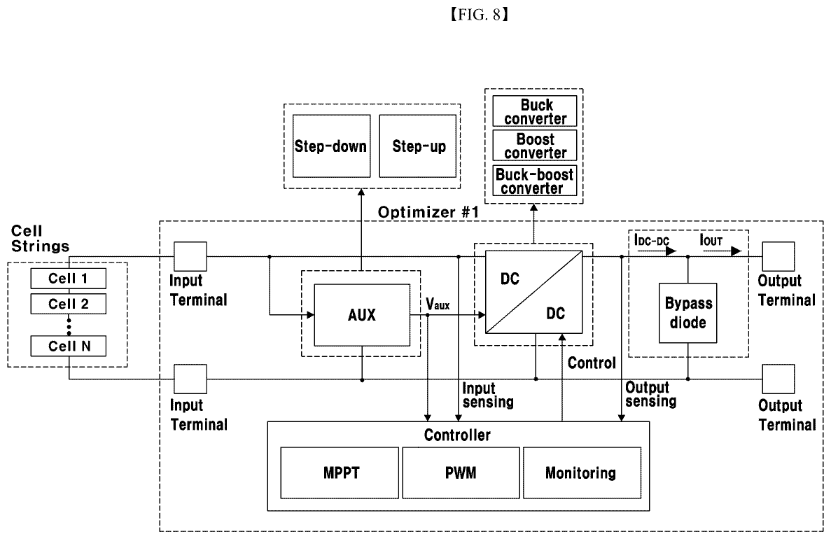

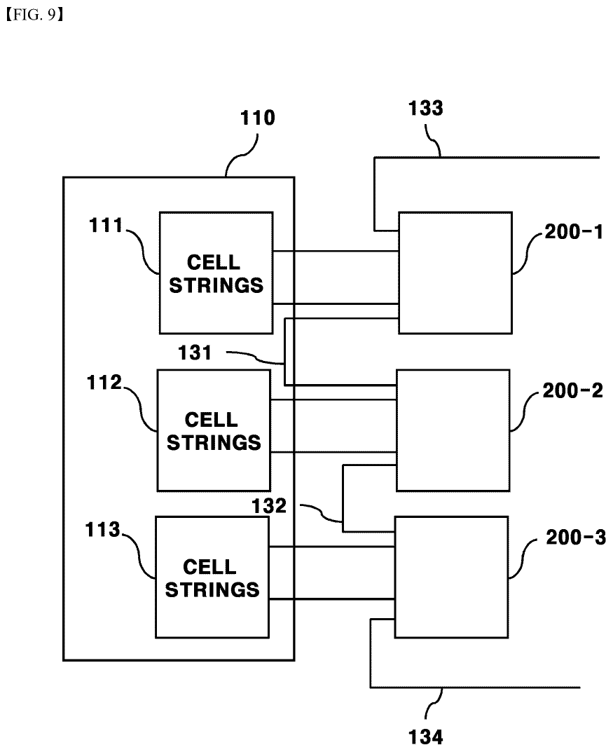

FIG. 7 is a block diagram of an optimizer module according to an embodiment of the present invention, and FIG. 8 shows an embodiment of an optimizer module according to an embodiment of the present invention, and FIG. 9 is a block diagram of a photovoltaic module according to another embodiment of the present invention. A detailed description of each configuration of FIGS. 7 to 9 corresponds to a detailed description of the photovoltaic modules of FIGS. 1 to 6, and the following redundant descriptions will be explained briefly.

The optimizer module (200) according to an embodiment of the present invention may include an input terminal (1211, 1212), a power conversion unit (1215), an output terminal (1213, 1214), and a control unit (1217), and may include an auxiliary power unit (1218) and a bypass unit (1216).

The input terminals (1211, 1212) are connected to the cell string (111). Two input terminals may be included to connect to both ends of the cell string (111). The output power of the cell string (111) may be inputted to the input terminals (1211, 1212). One of the input terminals (1211, 1212) may be connected to the (+) terminal of the cell string (111) and the other to the (−) terminal of the cell string (111).

The power conversion unit (1215) converts the power inputted to the input terminal (1211).

The power conversion unit (1215) converts the output power of each cell string (111) inputted through the above input terminals (1211, 1212) and outputs it to the above output terminals (1213, 1214). The power conversion unit (1215) can convert the voltage of the power of the cell string (111) and output it to the output terminal (1213, 1214). At this time, the power conversion unit (1215) can perform maximum power point tracking for each cell string (111). If some of the cell strings in a plurality of cell strings generate lower voltage than other cell strings due to shading, etc., it is necessary to output the voltage of the other cell strings as is without power conversion to reduce the voltage difference between each cell string to reduce loss and increase efficiency. At this time, the power conversion unit (1215) of each optimizer can adjust the power conversion so that the voltage between the cell strings is equal.

The optimizer module (200) according to an embodiment of the present invention may include an input terminal (1211, 1212), a power conversion unit (1215), an output terminal (1213, 1214), and a control unit (1217), and may include an auxiliary power unit (1218) and a bypass unit (1216).

The input terminals (1211, 1212) are connected to the cell string (111). Two input terminals may be included to connect to both ends of the cell string (111). The output power of the cell string (111) may be inputted to the input terminals (1211, 1212). One of the input terminals (1211, 1212) may be connected to the (+) terminal of the cell string (111) and the other to the (−) terminal of the cell string (111).

The power conversion unit (1215) converts the power inputted to the input terminal (1211).

The power conversion unit (1215) converts the output power of each cell string (111) inputted through the above input terminals (1211, 1212) and outputs it to the above output terminals (1213, 1214). The power conversion unit (1215) can convert the voltage of the power of the cell string (111) and output it to the output terminal (1213, 1214). At this time, the power conversion unit (1215) can perform maximum power point tracking for each cell string (111). If some of the cell strings in a plurality of cell strings generate lower voltage than other cell strings due to shading, etc., it is necessary to output the voltage of the other cell strings as is without power conversion to reduce the voltage difference between each cell string to reduce loss and increase efficiency. At this time, the power conversion unit (1215) of each optimizer can adjust the power conversion so that the voltage between the cell strings is equal.

The control unit (1217) controls the power conversion unit (1215) according to the power inputted to the input terminal (1211). The control unit (1217) controls the power conversion unit (1215) to convert the power inputted to the input terminal (1211). The output power of the cell string (111) inputted to the input terminal (1211) is maximized, and the control unit (1217) can control the power conversion unit (1215). The control unit can transmit control signals to each configuration to operate in the most suitable mode according to information such as input/output voltage, current, and temperature. It can also operate in the corresponding mode according to the control signal from the external control unit or the input from the user.

The control unit (1217) can detect and monitor data from the input terminal side, the output terminal side, and the inside of the optimizer module, and control the power conversion unit (1215) accordingly. For example, it can detect the power of the cell string (111) inputted to the input terminal (1211), the output power or output current of the power conversion unit (1215), or the current flowing through the output terminal (1213). In addition, the control unit (1217) can control the auxiliary power unit (1218), bypass unit (1216), etc.

The bypass unit (1216) may be connected in parallel between two output terminals (1213, 1214).

The bypass unit (1216) can create a bypass path between the output terminals (1213, 1214) that bypasses the connection to the power conversion unit (1215). A bypass path may be created to connect another optimizer module directly to the outside or to another optimizer module without performing power conversion. For example, when a failure occurs in a photovoltaic module containing a cell string, or when there is no or low power inputted to the power conversion unit (1215) due to an open input terminal (1211, 1212), the bypass unit (1216) can provide a bypass path. In addition, when a hot-spot occurs in the photovoltaic panel, the bypass unit (1216) can also suppress heat generation by providing a bypass path for the output current to lower the current value flowing through the photovoltaic panel. This prevents the increase in the amount of heat generated by the increase in the impedance of the photovoltaic panel when a current greater than the output current of the photovoltaic panel is forced through.

The bypass unit (1216) may be conducted if the first current outputted from the power conversion unit (1215) is lower than the second current flowing to the output terminal. If the first current converted and outputted from inside the optimizer module (200) is lower than the second current flowing through the output terminal (1213) connected to another optimizer module, the current may flow from another output terminal (1213) to inside the optimizer module (200). This may cause a failure or other error in the optimizer module (200) or a power waste. Therefore, in this case, the current flowing through the output terminal (1213) can flow through the bypass portion (1216) to bypass the optimizer module (200). Here, the bypass unit (1216) may include a diode. A diode allows current to flow in only one direction, so it can only bypass current in that direction.

The auxiliary power unit (1218) can generate auxiliary power using the power inputted to the input terminal (1211). The optimizer module (200) requires a power supply to convert power or perform control. The auxiliary power unit (1218) generates auxiliary power using the power inputted to the input terminal (1211) and can provide the generated auxiliary power to the power conversion unit (1215) or the control unit (1217).

The auxiliary power unit (1218) can operate in either step-down or step-up mode. The power inputted to the input terminal (1211) may vary depending on the amount of photovoltaic power generation, but the auxiliary power supply required for the operation of the power conversion unit (1215) or the control unit (1217) may not vary. Therefore, if the voltage of the input power is lower than the voltage of the auxiliary power, the auxiliary power unit (1218) operates in step-up mode, and if the voltage of the input power is higher than the voltage of the auxiliary power, the auxiliary power unit (1218) can operate in step-down mode.

The optimizer module (200) may be implemented with a circuit diagram such as that shown in FIG. 8. The optimizer module (200) is a module that optimizes the output power of the cell string and may include a power conversion unit (1215) such as a DC-DC converter and a control unit (1217) such as a controller. The DC-DC converter receives power generated from the cell string through the input terminal, converts the power, and outputs it through the output terminal. The controller can detect at least one parameter or control the DC-DC converter according to the detected parameter. The controller controls the DC-DC converter to maximize the power generated from the photovoltaic panel. It may also include a bypass diode (1216), which is a bypass unit. The bypass diode conducts when the second current, I_out, is higher than the first current, I_DC-DC, allowing I_out to be bypassed. It can also include an auxiliary power unit (1218) called AUX. The auxiliary power unit receives voltage from the cell string and generates the power needed for the controller and DC-DC converter. At this time, the auxiliary power unit can operate in at least one step-down or step-up mode.

Here, the DC-DC converter may be composed of at least one Buck, Boost, or Buck-boost converter, and the optimizer module connected to multiple cell strings may be connected in series. Through series connection, a voltage higher than the output voltage of the individual cell-string optimizer module can be formed.

A photovoltaic module according to an embodiment of the present invention may include a photovoltaic panel (110) comprising a plurality of cell strings (111, 112, 113) and a plurality of optimizer modules (200-1, 200-2, 200-3) for controlling the output power of each of the cell strings. At this time, each of the above optimizer modules may be spaced apart and placed in the area corresponding to each cell string.

The output terminals (1213, 1214) connected to the other optimizers may be connected via the connection unit (131) embedded in the photovoltaic panel (110). As shown in FIG. 9, the optimizer module (200-1) may be connected to another optimizer module (200-2) via the connection unit (131) embedded in the photovoltaic panel (110). The connection unit embedded in the photovoltaic panel (110) may include a bus bar or a cable. At this time, the output terminal may be directly connected to the bus bar, etc. embedded in the photovoltaic panel (110). At this time, the connection unit (131) embedded in the photovoltaic panel (110) may be drawn to the second surface of the photovoltaic module, such as the output terminals at both ends of the cell string. The connection unit (131) built into the photovoltaic panel (110) may be directly connected to the two output terminals (1213, 1214) of each optimizer mentioned above inside the optimizer. At this time, the connection unit (131) embedded in the photovoltaic panel (110) may be insulated and formed so that the cell strings and the inside of the photovoltaic panel (110) are not electrically connected to each other. When using the connection unit (131) embedded in the photovoltaic panel (110), the connection location may be limited, but it can be connected directly without a separate cable.

Alternatively, the output terminals (1213, 1214) connected to the other optimizers or the outside may be connected via an external connection unit (132) rather than the connection unit embedded in the photovoltaic panel (110). When using the connection unit (132) outside the photovoltaic panel (110), a conductor such as a cable is used, so the connection position or connection form can be freely implemented. However, the cables may be exposed to the outside, increasing the risk of electric shock.

Depending on the installation or working environment, the connection unit (131) built into the photovoltaic panel (110) or the connection unit (132) outside the photovoltaic panel (110) can be used.

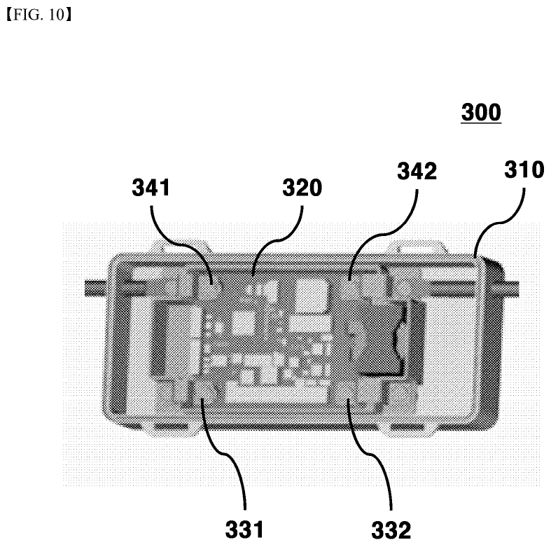

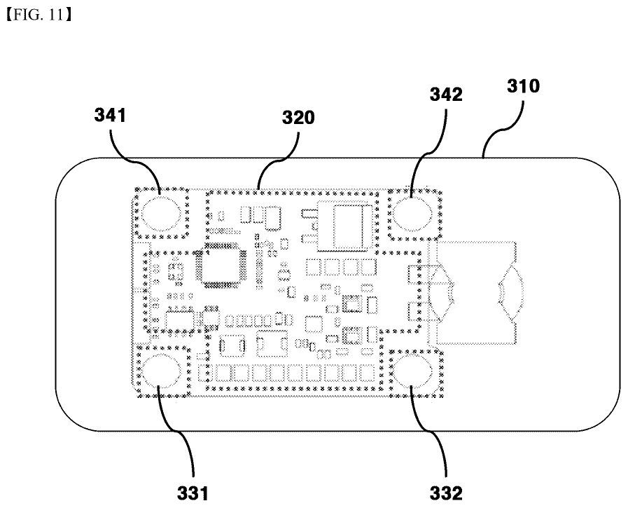

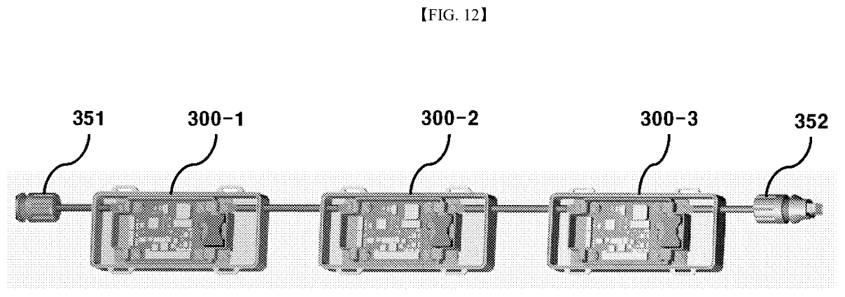

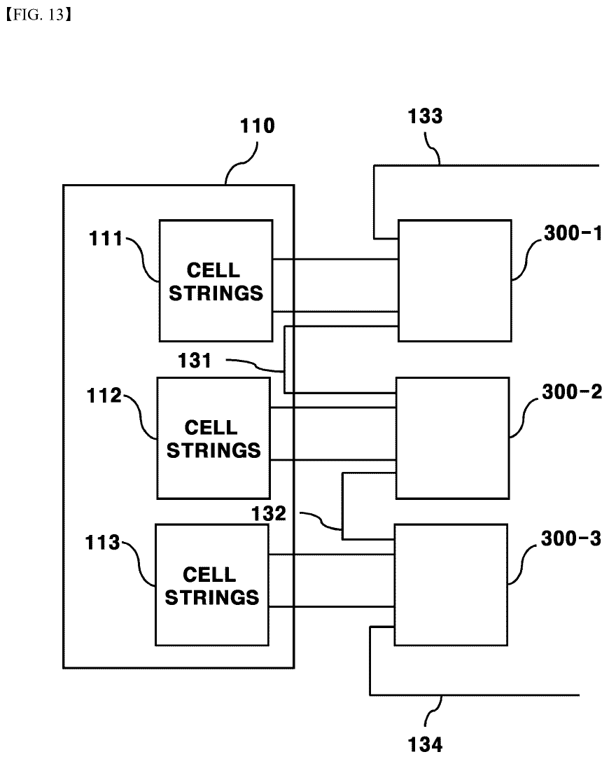

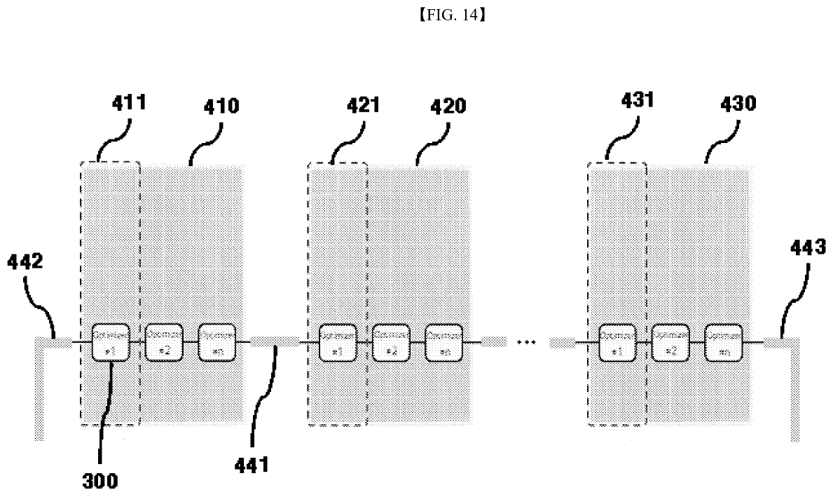

FIG. 10 is an isometric view of the optimizer module according to an embodiment of the present invention, FIG. 11 is a view of the inside of the case of the optimizer module according to an embodiment of the present invention, FIG. 12 is a connected relationship of multiple optimizer modules according to an embodiment of the present invention, and FIG. 13 is a block diagram of a photovoltaic module according to another embodiment of the present invention. FIG. 14 shows the connected relationship of multiple photovoltaic modules according to an embodiment of the present invention. A detailed description of each configuration of FIGS. 10 to 14 corresponds to a detailed description of the photovoltaic modules of FIGS. 1 to 9, and the following redundant descriptions will be explained briefly.

The optimizer module (300) according to an embodiment of the present invention may include a case and an optimizer (320) disposed inside the case. The optimizer (320) may include an input terminal (331,332), a power conversion unit (320), and an output terminal (342, 3434), and may include an auxiliary power unit and a bypass unit.

The case (310) may include a case body and a case cover (not shown) covering the case body, and may include an optimizer (320) that is disposed inside the case body. The optimizer (300) may include two input terminals (321, 332) and two output terminals (341, 342).

The two input terminals (331, 332) are connected to the output terminals at both ends of the cell string, and the optimizer (320) may include a power conversion unit that converts the output power of the cell string and a control unit that controls the power conversion unit according to the output power of the cell string.

The interior of the case (310) may be filled with a heat-dissipating material. Heat is generated when converting electricity, and the heat can be dissipated to the outside to prevent errors caused by heat. The interior of the case (310) may be filled with a silicon or epoxy material.

The interior of the case (310) may be formed with a waterproof structure. The case (310) may be formed on one surface of the photovoltaic module and, since it is located outdoors, can be exposed to rain, so it can be formed with a waterproof structure. As shown in FIG. 10, a waterproof structure can be formed on the optimizer (320) connected to each connection terminal. In other words, a case internal structure having a waterproof structure may be formed inside the case, and an optimizer (320) may be disposed inside the waterproof structure to protect the configuration disposed on the optimizer (320).

The optimizer (320) may be attachable to or detachable from the case (310) body. The optimizer (320) may be detachable from the case (310) body by connecting or disconnecting it with the input terminal (331, 332) or the output terminal (341, 342). At this time, each terminal may be screwed together. In the event of a failure in the optimizer (320), only the optimizer (320) may be detached and replaced or repaired, rather than the entire optimizer module (300). Alternatively, it may be disposed in the case (310) body in various ways, such as hook bonding or soldering.

The input terminals (331, 332) may be connected to the photovoltaic panel of the photovoltaic module in which the optimizer module (300) is mounted, so that the output power of the cell string can be inputted. The cell strings (111) connected in series may have two output terminals drawn out to the outside, and the output terminals may be drawn to the second surface of the photovoltaic module (100). The output terminals at both ends of each of the above mentioned cell strings may be directly connected inside the case (320) with the two input terminals (331, 332) of the optimizer module (300) mentioned above. The two input terminals (331, 332) may each be connected to the output terminals at both ends of the cell string (111) so that they can receive the power generated by the cell string (111).

The output terminals (341, 342) are connected to another optimizer module or to the outside. The output terminals (341, 342) may also include two output terminals. If the optimizer module is connected in series between optimizer modules and the optimizer module is located between other optimizer modules, the two output terminals (341, 342) are connected to two neighboring optimizer modules, respectively. The output of multiple optimizer modules may be connected in series to output maximum power to the outside. If the optimizer module is disposed at the position corresponding to the output terminal to the outside, one of the two output terminals (341, 342) can be connected to another optimizer module, and the other can be connected to the outside. Here, the outside is a configuration disposed outside the photovoltaic module, which may be a grid, load, or battery. Or, it may be a power conversion device such as an inverter. The outputs of each optimizer are connected in series and outputted to the outside.

The output terminals (341, 342) connected to the other optimizer modules may be connected via the connection unit (131) embedded in the photovoltaic panel (110). As shown in FIGS. 12 and 13, the optimizer module (300-1) may be connected to another optimizer module (300-2) via a connection unit (131) embedded in the photovoltaic panel (110). The connection unit embedded in the photovoltaic panel (110) may include a bus bar or a cable. At this time, the output terminal may be directly connected to the bus bar, etc. embedded in the photovoltaic panel (110). At this time, the connection unit (131) embedded in the photovoltaic panel (110) can be drawn to the second surface of the photovoltaic module (100) like the output terminals at both ends of the cell string. The connection unit (131) built into the photovoltaic panel (110) can be directly connected to the two output terminals (341, 342) of each optimizer module and inside the optimizer module case (310). At this time, the connection unit (131) embedded in the photovoltaic panel (110) may be insulated and formed so that the cell strings and the inside of the photovoltaic panel (110) are not electrically connected to each other. When using the connection unit (131) embedded in the photovoltaic panel (110), the connection location may be limited, but it can be connected directly without a separate cable.

Alternatively, the output terminals (341, 342) that are connected to the other optimizers or the outside may be connected via an external connection unit (132) rather than the connection unit embedded in the photovoltaic panel (110). When using the connection unit (132) outside the photovoltaic panel (110), a conductor such as a cable is used, so the connection position or connection form can be freely implemented. However, the cables may be exposed to the outside, increasing the risk of electric shock. Depending on the installation or working environment, the connection unit (131) built into the photovoltaic panel (110) or the connection (132) outside the photovoltaic panel (110) may be used.

The output terminals (341, 342) may be connected to another optimizer module or to an external device, and the output terminals (341, 342) may be connected in series when connected to another optimizer module. The output terminals (341, 342) may be connected to conductors such as cables or bus bars that are fed into the inside of the case (310) through holes formed on the outside of the case (310) by screwing them together.

The case (310) may include a case body and a case cover, and the case (310) may include a waterproof function. In addition, the interior of the case (310) may be filled with a material that allows heat transfer. For example, the interior of the case (310) may be filled with a material such as silicone or epoxy, which is easy to transfer heat. The optimizer, which optimizes the cell strings, can be easily replaced by being attachable to or detachable from the case (310). It can be electrically connected to the optimizer module of the cell strings disposed in other photovoltaic panels through the output terminal. At this time, the output terminal may be connected to a conductor such as a cable to facilitate connection with other photovoltaic panels. The output terminal may be connected through a conductor embedded in the photovoltaic panel, and the conductor embedded in the photovoltaic panel can be replaced with a cable that is not embedded in the photovoltaic panel.

The optimizer (320) may be formed with a circuit configuration that is disposed on a substrate inside the case (310). The optimizer (320) consists of input terminals (331, 332), a power conversion unit, and output terminals (342, 3434), and may include an auxiliary power unit and a bypass unit.

The power conversion unit converts the power inputted to the input terminal (331, 332). At this time, the control unit controls the power conversion unit according to the power inputted to the input terminal (331, 332). The control unit can control the power conversion unit so that the output power of the cell string is maximized. The power conversion unit may include at least one of a buck converter, a boost converter, and a buck-boost converter.

The bypass unit may be connected in parallel between the two output terminals (341, 342) and conduct current between the output terminals to form a bypass path. The auxiliary power unit can generate auxiliary power using the output power of the cell string and provide it to the power conversion unit or control unit.

A photovoltaic module according to an embodiment of the present invention may include a photovoltaic panel (110) comprising a plurality of cell strings (111, 112, 113) and a plurality of optimizer modules (300-1, 300-2, 300-3) for controlling the output power of each of the said cell strings. At this time, each of the above optimizer modules may be spaced apart from each other and disposed in the area corresponding to each cell string.

The output terminals (341, 342) connected to the other optimizers mentioned above may be connected via the connection unit (131) embedded in the photovoltaic panel (110). As shown in FIGS. 12 and 13, the optimizer module (300-1) may be connected to another optimizer module (300-2) via the connection unit (131) embedded in the photovoltaic panel (110). The connection unit (131) embedded in the photovoltaic panel (110) may be insulated and formed so that the cell strings and the inside of the photovoltaic panel (110) are not electrically connected to each other. When using the connection unit (131) embedded in the photovoltaic panel (110), the connection location may be limited, but it can be connected directly without a separate cable.

Alternatively, the output terminals (341, 342) connected to the other optimizer or the outside may be connected via an external connection unit (132) rather than the connection unit embedded in the photovoltaic panel (110). When using the connection unit (132) outside the photovoltaic panel (110), a conductor such as a cable is used, so the connection location or connection form can be freely implemented. However, the cables may be exposed to the outside, increasing the risk of electric shock. Depending on the installation or working environment, the connection unit (131) built into the photovoltaic panel (110) or the connection unit (132) outside the photovoltaic panel (110) can be used.

Photovoltaic modules (410, 420, 430) may be connected in multiple numbers. As shown in FIG. 14, multiple photovoltaic modules (410, 420, 430) may be connected in series with each other through a conductor (441) or connected to the outside through a conductor (442, 443). Each photovoltaic module (410) may include a photovoltaic panel (411) and the optimizer module (300) described above.

As mentioned above, the optimizer module may be located in a position corresponding to the output terminal of the cell string, thereby reducing the number of cables connecting the photovoltaic panel and the optimizer and facilitating operation.

One having ordinary skill in the art will understand that the embodiments of the present invention can be implemented in modified forms that do not deviate from the essential features of the above-described embodiments. Therefore, the disclosed methods should be considered in a descriptive rather than a limiting sense. The scope of the present invention is not described in the foregoing description but in the patent claims, and all differences within the equivalent scope thereof should be construed as being included in the present invention.

1-10. (canceled)

11. An optimizer module, comprising:
a case body;
a case cover covering the case body; and
an optimizer disposed inside the case body,
wherein the optimizer includes two input terminals and two output terminals.

12. The optimizer module of claim 11, wherein the two input terminals are connected to the output terminals at both ends of cell string, and
wherein the optimizer comprises:
a power conversion unit configured to convert output power of the cell string; and
a control unit configured to control the power conversion unit according to the output power of the cell string.

13. The optimizer module of claim 11, wherein the output terminals are connected to an other optimizer module or outside.

14. The optimizer module of claim 13, wherein the output terminal is connected in series when connected to the other optimizer module.

15. The optimizer module of claim 11, wherein inside of the case body is filled with a heat-dissipating material.

16. The optimizer module of claim 11, wherein the case body and the case cover are formed of waterproof structure.

17. The optimizer module of claim 11, wherein the optimizer is attachable to and detachable from the case body.

18. The optimizer module of claim 11, wherein the optimizer comprises a bypass unit connected in parallel between the two output terminals.

19. The optimizer module of claim 12, wherein the optimizer comprises an auxiliary power unit configured to generate an auxiliary power source using the output power of the cell string.

20. A photovoltaic module, comprising:
a photovoltaic panel comprising a plurality of cell strings; and
a plurality of optimizer modules each configured to control output power of each of the cell strings,
wherein the optimizer module comprises:
a case body;
a case cover covering the case body; and
an optimizer disposed inside the case body, and
wherein the optimizer includes two input terminals and two output terminals.

21. The photovoltaic module of claim 20, wherein the plurality of the optimizer modules are spaced apart from each other and disposed in an area corresponding to each of cell strings.

22. The photovoltaic module of claim 20, the plurality of the optimizer modules are connected in series with each other via a connection unit embedded in the photovoltaic panel.

23. The photovoltaic module of claim 20, the plurality of the optimizer modules are connected to each other or to an other photovoltaic module via a connection unit at outside of the photovoltaic panel.

24. The photovoltaic module of claim 20, wherein the two input terminals are connected to the output terminals at both ends of one of cell strings, and
wherein the optimizer comprises:
a power conversion unit configured to convert output power of the cell string; and
a control unit configured to control the power conversion unit according to the output power of the cell string.

25. The photovoltaic module of claim 20, wherein the output terminals are connected to an other optimizer module or outside.

26. The photovoltaic module of claim 25, wherein the output terminal is connected in series when connected to the other optimizer module.

27. The photovoltaic module of claim 20, wherein inside of the case body is filled with a heat-dissipating material.

28. The photovoltaic module of claim 20, wherein the case body and the case cover are formed of waterproof structure.

29. The photovoltaic module of claim 20, wherein the optimizer is attachable to and detachable from the case body.

30. The photovoltaic module of claim 20, wherein the optimizer comprises a bypass unit connected in parallel between the two output terminals.
